(19) United States
(12) Patent Application Publication
(10) Pub. No.: US 2026/0157145 A1
(43) Pub. Date: Jun. 4, 2026

(54) APPARATUS FOR FORMING THIN FILM, AND ELECTRONIC DEVICE FABRICATED BY THE APPARATUS

(71) Applicant: Samsung Display Co., Ltd., Yongin-si (KR)

(72) Inventors: Jin Won BAEK, Yongin-si (KR); Yeong Jun KIM, Yongin-si (KR); Lae Ho KIM, Yongin-si (KR); Bong Sik NOH, Yongin-si (KR); Jeong Ho YI, Yongin-si (KR); Tae Ho LEE, Yongin-si (KR); Myung Soo HUH, Yongin-si (KR); Dong Hoon HYUN, Yongin-si (KR)

(21) Appl. No.: 19/317,984

(22) Filed: Sep. 3, 2025

(30) Foreign Application Priority Data
Dec. 4, 2024 (KR) 10-2024-0178712

(51) Int. Cl. H01L 21/683; H10K 59/12

(52) U.S. Cl. CPC H10P 72/722; H10K 59/1201

(57) ABSTRACT

An apparatus for providing a thin film and an electronic device including a display device fabricated by the apparatus are disclosed. The apparatus may include an electrostatic chuck to absorb and support a substrate and a supply nozzle to supply chemical liquid onto the substrate, and wherein the electrostatic chuck includes a base, at least one first electrode pattern on the base, at least one second electrode pattern provided on the base and spaced and/or apart (e.g., spaced apart or separated) from the first electrode pattern (e.g., the at least one first electrode pattern), and at least one ground pattern provided on the base and spaced and/or apart (e.g., spaced apart or separated) from the first electrode pattern (e.g., the at least one first electrode pattern) and the second electrode pattern (e.g., the at least one second electrode pattern).

### CROSS-REFERENCE TO RELATED APPLICATION

The present application claims priority to and the benefit of Korean Patent Application No. 10-2024-0178712, filed on Dec. 4, 2024, in the Korean Intellectual Property Office, the entire disclosure of which is incorporated herein by reference.

### BACKGROUND

### 1. Field

One or more embodiments of the present disclosure relate to an apparatus for forming or providing a thin film and an electronic device fabricated by the apparatus.

### 2. Description of the Related Art

Organic light-emitting display devices utilize the phenomenon that electrons injected from a cathode and holes injected from an anode recombine in an organic thin film to form excitons, and light of a particular wavelength generated as energy is released if (e.g., when) the excitons relax from an excited state to the ground state.

In organic light-emitting display devices, chemical liquid printing technique may be used as a method to form or provide an organic material and/or a metal utilized as an electrode on a substrate. The chemical liquid printing technique is a method to form or provide a thin film by supplying a chemical liquid onto a substrate utilizing a supply nozzle and curing the chemical liquid supplied onto the substrate.

Because there may be protruding portions on the substrate, the surface of the thin film may not be formed or provided evenly during the process of curing the chemical liquid to form or provide the thin film.

### SUMMARY

One or more aspects of embodiments of the present disclosure are directed toward an apparatus for forming or providing a thin film that may form or provide a thin film on a substrate so that (e.g., such that) the surface is even (e.g., substantially even) and an electronic device fabricated by the apparatus.

Additional aspects of embodiments will be set forth in part in the description which follows and, in part, will be apparent from the description or may be learned by practice of the presented embodiments of the disclosure.

However, aspects and features of embodiments of the present disclosure are not restricted to those set forth herein. The above and other aspects and features of certain embodiments of the present disclosure will become more apparent to one of ordinary skill in the art to which the present disclosure pertains by referencing the detailed description of the present disclosure given.

According to one or more embodiments of the present disclosure, an apparatus for forming or providing a thin film includes an electrostatic chuck to absorb and support a substrate and a supply nozzle to supply chemical liquid onto the substrate, and wherein the electrostatic chuck includes a base, at least one first electrode pattern disposed or provided on the base, at least one second electrode pattern disposed or provided on the base and spaced and/or apart (e.g., spaced apart or separated) from the first electrode pattern (e.g., the at least one first electrode pattern), and at least one ground pattern disposed or provided on the base and spaced and/or apart (e.g., spaced apart or separated) from the first electrode pattern (e.g., the at least one first electrode pattern) and the second electrode pattern (e.g., the at least one second electrode pattern).

The at least one first electrode pattern may include a plurality of first electrode patterns, the at least one second electrode pattern may include a plurality of second electrode patterns, and the at least one ground pattern may include a plurality of ground patterns, and wherein the plurality of first electrode patterns, the plurality of second electrode patterns, and the plurality of ground patterns are arranged or provided sequentially and repeatedly.

The second electrode patterns (e.g., the plurality of second electrode patterns) and the ground patterns (e.g., the plurality of ground patterns) may be disposed or provided between the first electrode patterns (e.g., the plurality of first electrode patterns).

One of the plurality of second electrode patterns may be disposed or provided between one of the plurality of first electrode patterns and an other one of the first electrode patterns (e.g., the plurality of first electrode patterns), and wherein one of the ground patterns (e.g., the plurality of ground patterns) is spaced and/or apart (e.g., spaced apart or separated) from the other one of the first electrode patterns (e.g., the plurality of first electrode patterns) so that (e.g., such that) the other one of the first electrode patterns (e.g., the plurality of first electrode patterns) is disposed or provided between the one of the ground patterns (e.g., the plurality of ground patterns) and the one of the second electrode patterns (e.g., the plurality of second electrode patterns).

The first electrode patterns (e.g., the plurality of first electrode patterns), the second electrode patterns (e.g., the plurality of second electrode patterns), and the ground patterns (e.g., the plurality of ground patterns) may be extended in a first direction, and wherein the first electrode patterns (e.g., the plurality of first electrode patterns), the second electrode patterns (e.g., the plurality of second electrode patterns), and the ground patterns (e.g., the plurality of ground patterns) are spaced and/or apart (e.g., spaced apart or separated) from one another in a second direction crossing (e.g., intersecting) the first direction.

The first electrode patterns (e.g., the plurality of first electrode patterns), the second electrode patterns (e.g., the plurality of second electrode patterns), and the ground patterns (e.g., the plurality of ground patterns) may be arranged or provided in an order of a first electrode pattern, a second electrode pattern, a first electrode pattern (e.g., an other first electrode pattern), and a ground pattern.

The substrate may include at least one flat (e.g., substantially flat) portion formed or provided on the substrate and at least one protruding portion protruding from the flat portion (e.g., the at least one flat portion) upwardly of the substrate, and wherein the at least one flat portion includes a plurality of flat (e.g., substantially flat) portions and the at least one protruding portion includes a plurality of protruding portions, and the flat portions (e.g., the plurality of flat portions) and the protruding portions (e.g., the plurality of protruding portions) are arranged or provided alternately with each other, and wherein the plurality of first electrode patterns, the plurality of second electrode patterns, and the plurality of ground patterns overlap with the plurality of flat portions.

The flat portions (e.g., the plurality of flat portions) and the protruding portions (e.g., the plurality of protruding portions) may be extended in the first direction and arranged or provided alternately in the second direction.

The plurality of flat portions may include a first flat (e.g., substantially flat) portion, a second flat (e.g., substantially flat) portion, a third flat (e.g., substantially flat) portion, and a fourth flat (e.g., substantially flat) portion, and wherein one of the first electrode patterns (e.g., the plurality of first electrode patterns) overlaps with the first flat portion, one of the second electrode patterns (e.g., the plurality of second electrode patterns) overlaps with the second flat portion, an other one of the first electrode patterns (e.g., the plurality of first electrode patterns) overlaps with the third flat portion, and one of the ground patterns (e.g., the plurality of ground patterns) overlaps with the fourth flat portion.

Direct current (DC) voltage may be applied to the first electrode pattern (e.g., the at least one first electrode pattern), alternating current (AC) voltage may be applied to the second electrode pattern (e.g., the at least one second electrode pattern), and ground voltage may be applied to the ground pattern (e.g., the at least one ground pattern).

A maximum value of the AC voltage applied to the second electrode pattern (e.g., the at least one second electrode pattern) may be equal to or less than the DC voltage applied to the first electrode pattern (e.g., the at least one first electrode pattern).

According to one or more embodiments of the present disclosure, an electronic device includes a display device fabricated by an apparatus for forming or providing a thin film, wherein the apparatus includes an electrostatic chuck to absorb and support a substrate and a supply nozzle to supply chemical liquid onto the substrate, and wherein the electrostatic chuck includes a base, at least one first electrode pattern disposed or provided on the base, at least one second electrode pattern disposed or provided on the base and spaced and/or apart (e.g., spaced apart or separated) from the first electrode pattern (e.g., the at least one first electrode pattern), and at least one ground pattern disposed or provided on the base and spaced and/or apart (e.g., spaced apart or separated) from the first electrode pattern (e.g., the at least one first electrode pattern) and the second electrode pattern (e.g., the at least one second electrode pattern).

The at least one first electrode pattern may include a plurality of first electrode patterns, the at least one second electrode pattern may include a plurality of second electrode patterns, and the at least one ground pattern may include a plurality of ground patterns, and wherein the plurality of first electrode patterns, the plurality of second electrode patterns, and the plurality of ground patterns are arranged or provided sequentially and repeatedly.

The second electrode patterns (e.g., the plurality of second electrode patterns) and the ground patterns (e.g., the plurality of ground patterns) may be disposed or provided between the first electrode patterns (e.g., the plurality of first electrode patterns).

One of the plurality of second electrode patterns may be disposed or provided between one of the plurality of first electrode patterns and an other one of the first electrode patterns (e.g., the plurality of first electrode patterns), and wherein one of the ground patterns (e.g., the plurality of ground patterns) is spaced and/or apart (e.g., spaced apart or separated) from the other one of the first electrode patterns (e.g., the plurality of first electrode patterns) so that (e.g., such that) the other one of the first electrode patterns (e.g., the plurality of first electrode patterns) is disposed or provided between the one of the ground patterns (e.g., the plurality of ground patterns) and the one of the second electrode patterns (e.g., the plurality of second electrode patterns).

The first electrode patterns (e.g., the plurality of first electrode patterns), the second electrode patterns (e.g., the plurality of second electrode patterns), and the ground patterns (e.g., the plurality of ground patterns) may be extended in a first direction, and wherein the first electrode patterns (e.g., the plurality of first electrode patterns), the second electrode patterns (e.g., the plurality of second electrode patterns), and the ground patterns (e.g., the plurality of ground patterns) are spaced and/or apart (e.g., spaced apart or separated) from one another in a second direction crossing (e.g., intersecting) the first direction.

The substrate may include at least one flat (e.g., substantially flat) portion formed or provided on the substrate and at least one protruding portion protruding from the flat portion (e.g., the at least one flat portion) upwardly of the substrate, and wherein the at least one flat portion includes a plurality of flat (e.g., substantially flat) portions and the at least one protruding portion includes a plurality of protruding portions, and the flat portions (e.g., the plurality of flat portions) and the protruding portions (e.g., the plurality of protruding portions) are arranged or provided alternately with each other, and wherein the plurality of first electrode patterns, the plurality of second electrode patterns, and the plurality of ground patterns overlap with the plurality of flat portions.

The flat portions (e.g., the plurality of flat portions) and the protruding portions (e.g., the plurality of protruding portions) may be extended in the first direction and arranged or provided alternately in the second direction.

The plurality of flat portions may include a first flat (e.g., substantially flat) portion, a second flat (e.g., substantially flat) portion, a third flat (e.g., substantially flat) portion, and a fourth flat (e.g., substantially flat) portion, and wherein one of the first electrode patterns (e.g., the plurality of first electrode patterns) overlaps with the first flat portion, one of the second electrode patterns (e.g., the plurality of second electrode patterns) overlaps with the second flat portion, an other one of the first electrode patterns (e.g., the plurality of first electrode patterns) overlaps with the third flat portion, and one of the ground patterns (e.g., the plurality of ground patterns) overlaps with the fourth flat portion.

DC voltage may be applied to the first electrode pattern (e.g., the at least one first electrode pattern), AC voltage may be applied to the second electrode pattern (e.g., the at least one second electrode pattern), and ground voltage may be applied to the ground pattern (e.g., the at least one ground pattern).

According to one or more embodiments of the present disclosure, by disposing or providing first electrode patterns (e.g., a plurality of first electrode patterns), second electrode patterns (e.g., a plurality of second electrode patterns), and ground patterns (e.g., a plurality of ground patterns) on an electrostatic chuck of an apparatus for forming or providing a thin film which absorbs and supports a substrate and applying DC voltage, AC voltage, and ground voltage to chemical solution supplied to the substrate, it may be feasible to maintain the surface of the chemical liquid even (e.g., substantially even) so that (e.g., such that) the surface of the thin film formed or provided on the substrate may be even (e.g., substantially even).

The aspects and features of embodiments of the present disclosure are not limited to those set forth herein, and other aspects, features, and/or embodiments of the present disclosure will become better understood through the detailed description, the appended claims and equivalents thereof, and the accompanying drawings.

### BRIEF DESCRIPTION OF THE DRAWINGS

The above and other aspects and features of certain embodiments of the present disclosure will become more apparent from the following description taken in conjunction with the accompanying drawings, in which:

FIG. 1 is a view schematically illustrating an apparatus for forming or providing a thin film according to one or more embodiments of the present disclosure;

FIG. 2 is a plan view of the electrostatic chuck of FIG. 1;

FIG. 3 is an enlarged view of portion A of FIG. 1;

FIG. 4 is a view illustrating the supply nozzle of FIG. 1 that supplies a chemical liquid onto a substrate;

FIG. 5 is an enlarged view of portion B of FIG. 4;

FIG. 6 is a view illustrating that AC voltage being less than the DC voltage applied to the first electrode pattern is applied to the second electrode pattern in FIG. 5;

FIG. 7 is a view illustrating the states of FIGS. 5 and 6 at the same time;

FIG. 8 is a view illustrating that the surface of the chemical liquid becomes even (e.g., substantially even) after the process of FIG. 7;

FIG. 9 is a plan view illustrating a display device fabricated by the apparatus for forming or providing a thin film according to one or more embodiments of the present disclosure if (e.g., when) a connecting member is folded;

FIG. 10 is a plan view illustrating the display device of FIG. 9 if (e.g., when) the connecting member is unfolded;

FIG. 11 is a side view illustrating a part of FIG. 10; and

FIG. 12 is a perspective view of an electronic device fabricated by the apparatus for forming or providing a thin film according to one or more embodiments of the present disclosure.

### DETAILED DESCRIPTION

In order to fully understand the aspects and features of the present disclosure, the subject matter of the present disclosure will be described below in more detail with reference to the accompanying drawings. The subject matter of the present disclosure may, however, be embodied in one or more forms and should not be construed as being limited to one or more embodiments set forth herein, and one or more changes and modifications can be made. Rather, these embodiments are provided as examples so that this disclosure will be thorough and complete and will fully convey the aspects and features of the present disclosure to those skilled in the art to which the present disclosure pertains.

The utilization of “may” if (e.g., when) describing embodiments of the present disclosure refers to “one or more embodiments of the present disclosure.”

In the context of the present disclosure and unless otherwise defined, the terms, “use,” “using,” and “used,” may be considered synonymous with the terms, “utilize,” “utilizing,” and “utilized,” respectively.

As used herein, the term, “and/or,” includes any and all combinations of one or more of the associated listed items. For example, “A and/or B” indicates cases where it is A, B, or both (e.g., simultaneously) A and B.

Throughout the present disclosure, the expression “at least one of a, b, or c” indicates only a, only b, only c, both (e.g., simultaneously) a and b, both (e.g., simultaneously) a and c, both (e.g., simultaneously) b and c, all of a, b, and c, or variations thereof.

The singular forms, “a,” “an,” and “the,” include plural references unless the context clearly requires otherwise.

In the present disclosure, the terms, “includes,” “including,” “has,” “having,” and/or the like, are intended to designate the presence of a feature, a number, a step, an operation, a component, a part, or a combination thereof as described in the specification and should not be understood to preclude the presence or possibility of addition of one or more other features, numbers, steps, operations, components, parts, or combinations thereof. For example, it should be understood that the term, “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, a phrase “an element A on an element B” refers to that the element A may be disposed or provided directly on the element B and/or the element A may be disposed or provided indirectly on the element B via an other element C. In contrast, if (e.g., when) an element A is referred to as being “directly on” an element B, there are no intervening elements present therebetween.

Like reference numerals denote like elements throughout the descriptions.

The figures, dimensions, ratios, angles, and/or numbers of elements given in the drawings are just illustrative but not limitative in all aspects.

The terms, such as “first,” “second,” and/or the like, are used to distinguish between the elements that the terms describe, and thus these terms are not necessarily intended to indicate temporal or other prioritization of the elements. These terms are used just to distinguish one element from another. Accordingly, as used herein, a first element may be a second element within the scope of the present disclosure.

The aspects and features of one or more embodiments of the present disclosure may be combined partially or totally. As will be clearly appreciated by those skilled in the art, one or more suitable interactions and operations may be feasible. One or more embodiments of the present disclosure may be practiced individually or in combination.

As used herein, the terms, “substantially,” “about,” and/or the like, are used as terms of approximation and not as terms of degree and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in the present disclosure is intended to include all higher numerical limitations subsumed therein. Accordingly, Applicant reserves the right to amend this specification, including the claims, to expressly recite any sub-range subsumed within the ranges expressly recited herein.

In the context of the present disclosure and unless otherwise defined, plan view is an orthographic projection of a three-dimensional object from the position of a horizontal plane that intersects the object. For example, it is a top-down view, illustrating the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

Hereinafter, one or more embodiments of the present disclosure will be described in more detail with reference to the accompanying drawings.

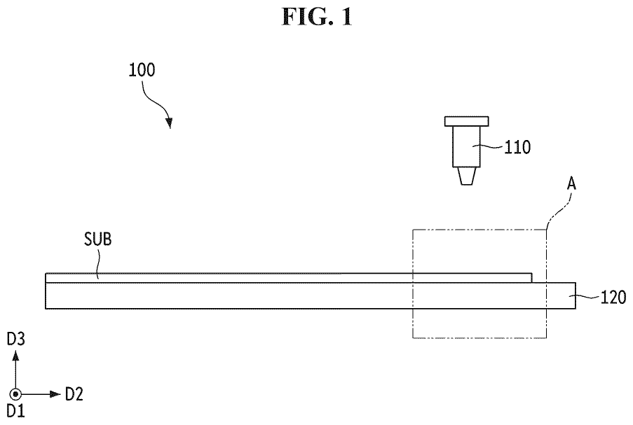

FIG. 1 is a view schematically illustrating an apparatus for forming or providing a thin film according to one or more embodiments of the present disclosure.

Referring to FIG. 1, an apparatus 100 for forming or providing a thin film according to one or more embodiments of the present disclosure may include a supply nozzle 110 and an electrostatic chuck 120.

The supply nozzle 110 may be disposed or provided above the substrate SUB to supply a chemical liquid MF onto the substrate SUB. The supply nozzle 110 may be horizontally (e.g., substantially horizontally) movable above the substrate SUB so that (e.g., such that) it may supply the chemical liquid MF to the entire (e.g., substantially entire) upper area of the substrate SUB. While the supply nozzle 110 may be horizontally (e.g., substantially horizontally) movable above the substrate SUB, the supply nozzle 110 may be fixed and the substrate SUB may be horizontally (e.g., substantially horizontally) movable so that (e.g., such that) the chemical liquid MF may be supplied to the entire (e.g., substantially entire) upper area of the substrate SUB. The supply nozzle 110 may be connected to a separate chemical liquid storage so that (e.g., such that) it may receive the chemical liquid MF from the chemical liquid storage.

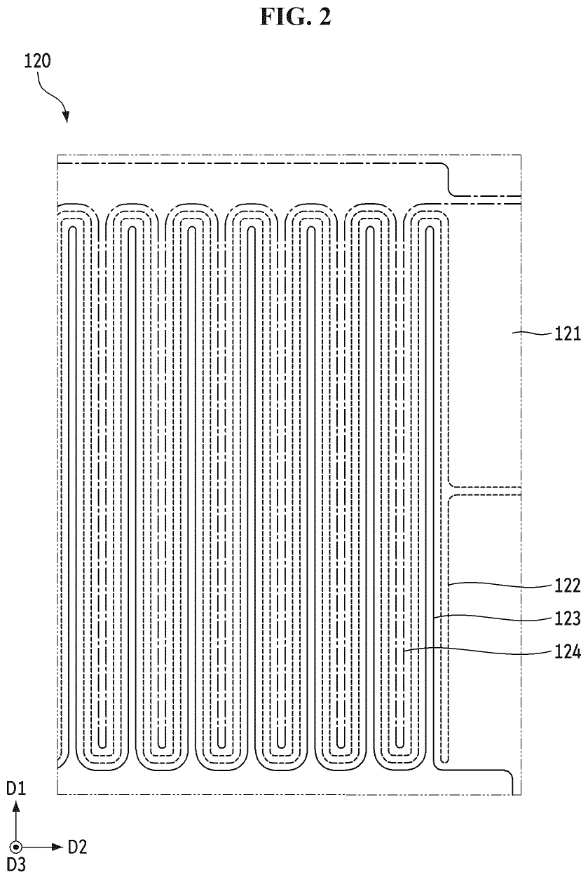

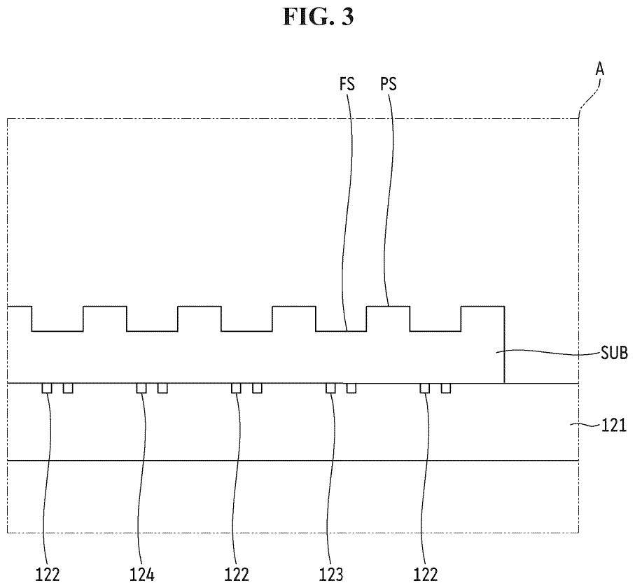

FIG. 2 is a plan view of the electrostatic chuck of FIG. 1. FIG. 3 is an enlarged view of portion A of FIG. 1.

Referring to FIGS. 2 and 3, the electrostatic chuck 120 may adsorb and support the substrate SUB. Before describing the electrostatic chuck 120, the substrate SUB that is absorbed and supported by the electrostatic chuck 120 will first be described in more detail.

The substrate SUB may be made of an insulating (e.g., electrically insulating) material, such as glass, quartz, and/or a polymer resin. The substrate SUB may be a rigid substrate or a flexible substrate that may be bent, folded, rolled, and/or the like. The substrate SUB may be provided as a rectangular (e.g., substantially rectangular) plate having a pair of longer sides extended in a first direction D1 and a pair of shorter sides extended in a second direction D2. In one or more embodiments, the substrate SUB may be a plate having a rectangular (e.g., substantially rectangular) shape if (e.g., when) viewed from the top.

A flat portion FS and a protruding portion PS may be formed or provided on the substrate SUB. The flat portion FS may be the upper surface of the substrate SUB, and the protruding portion PS may protrude upwardly from the flat portion FS in the thickness direction of the substrate SUB. In one or more embodiments, the protruding portion PS may protrude from the flat portion FS in the third direction D3.

There may be a plurality of flat portions FS and a plurality of protruding portions PS. The flat portions FS and the protruding portions PS may be arranged or provided alternately. For example, a plurality of flat portions FS and a plurality of protruding portions PS may be extended in the first direction D1. The plurality of flat portions FS and the plurality of protruding portions PS may be arranged or provided alternately in the second direction D2.

The electrostatic chuck 120 may include a base 121, a first electrode pattern 122, a second electrode pattern 123, and a ground pattern 124.

The base 121 may be disposed or provided under the substrate SUB to support the substrate SUB. The base 121 may be provided as a rectangular (e.g., substantially rectangular) plate having a pair of longer sides extended in a first direction D1 and a pair of shorter sides extended in a second direction D2. In one or more embodiments, the base 121 may be a plate having a rectangular (e.g., substantially rectangular) shape if (e.g., when) viewed from the top. The size of the base 121 may be larger than the size of the substrate SUB if (e.g., when) viewed from the top. The base 121 may include ceramic, but this is just illustrative. The material of the base 121 may not be limited thereto. For example, the base 121 may include aluminum (Al), titanium (Ti), stainless steel, alumina (Al₂O₃), yttrium oxide (Y₂O₃), and/or aluminum nitride. The base 121 may support the first electrode pattern 122, the second electrode pattern 123, and the ground pattern 124.

The first electrode pattern 122 may be disposed or provided at the upper surface of the base 121. While the first electrode pattern 122 may be disposed or provided on the upper surface of the base 121, it may also be disposed or provided such that it is embedded from the upper surface of the base 121 in the thickness direction of the base 121.

There may be a plurality of first electrode patterns 122, and the first electrode patterns 122 may be spaced and/or apart (e.g., spaced apart or separated) from each other on the base 121. For example, the first electrode patterns 122 may be extended in the first direction D1, and the first electrode patterns 122 extended in the first direction D1 may be spaced and/or apart (e.g., spaced apart or separated) from each other in the second direction D2.

The first electrode patterns 122 may overlap with the flat portions FS of the substrate SUB, and a DC voltage may be applied to the first electrode patterns 122. For example, the constant voltage of 2 kV may be applied to the first electrode patterns 122.

The second electrode pattern 123 may be disposed or provided at the upper surface of the base 121. While the second electrode pattern 123 may be disposed or provided on the upper surface of the base 121, it may also be disposed or provided such that it is embedded from the upper surface of the base 121 in the thickness direction of the base 121.

There may be a plurality of second electrode patterns 123, and the second electrode patterns 123 may be spaced and/or apart (e.g., spaced apart or separated) from each other on the base 121. For example, the second electrode patterns 123 may be extended in the first direction D1, and the second electrode patterns 123 extended in the first direction D1 may be spaced and/or apart (e.g., spaced apart or separated) from each other in the second direction D2. The second electrode patterns 123 may be spaced and/or apart (e.g., spaced apart or separated) from the first electrode patterns 122 in the second direction D2.

The second electrode patterns 123 may overlap with the flat portions FS of the substrate SUB, and AC voltage may be applied to the second electrode patterns 123. The maximum value of the AC voltage applied to the second electrode patterns 123 may be equal to or less than the DC voltage applied to the first electrode pattern 122. For example, if (e.g., when) the DC voltage of 2 kV is applied to the first electrode pattern 122, the AC voltage applied to the second electrode pattern 123 may be equal to or lower than 2 kV. An AC voltage in the range of −2 kV to 2 kV may be applied to the second electrode pattern 123.

The ground pattern 124 may be disposed or provided at the upper surface of the base 121. While the ground pattern 124 may be disposed or provided on the upper surface of the base 121, it may also be disposed or provided such that it is embedded from the upper surface of the base 121 in the thickness direction of the base 121.

There may be a plurality of ground patterns 124, and the ground patterns 124 may be spaced and/or apart (e.g., spaced apart or separated) from each other on the base 121. For example, the ground patterns 124 may be extended in the first direction D1, and the ground patterns 124 extended in the first direction D1 may be spaced and/or apart (e.g., spaced apart or separated) from each other in the second direction D2. The ground patterns 124 may be spaced and/or apart (e.g., spaced apart or separated) from the first electrode patterns 122 and the second electrode patterns 123 in the second direction D2.

The ground patterns 124 may overlap with the flat portions FS of the substrate SUB, and a ground voltage may be applied to the ground patterns 124. For example, the constant voltage of 0 kV may be applied to the ground patterns 124.

The first electrode patterns 122, the second electrode patterns 123, and the ground patterns 124 may be arranged or provided sequentially and repeatedly. For example, the second electrode patterns 123 and the ground patterns 124 may be between the first electrode patterns 122. For example, one of the second electrode patterns 123 may be disposed or provided between one of the plurality of first electrode patterns 122 and an other one of the plurality of first electrode patterns 122. In one or more embodiments, one ground pattern 124 may be spaced and/or apart (e.g., spaced apart or separated) from the other first electrode pattern 122 such that the other first electrode pattern 122 is disposed or provided between one of the plurality of ground patterns 124 and one second electrode pattern 123. In one or more embodiments, the first electrode patterns 122, the second electrode patterns 123, and the ground patterns 124 may be arranged or provided in the second direction D2 in the order of a first electrode pattern 122, a second electrode pattern 123, a first electrode pattern 122, and a ground pattern 124.

The first electrode patterns 122, the second electrode patterns 123, and the ground patterns 124 may overlap with a plurality of flat portions FS of the substrate SUB. For example, the flat portions FS of the substrate SUB may include a first flat portion FS, a second flat portion FS, a third flat portion FS, a fourth flat portion FS, and a fifth flat portion FS. The first flat portion FS may be located or provided at the rightmost position of FIG. 3, while the fifth flat portion FS may be located or provided at the leftmost position of FIG. 3. In one or more embodiments, the flat portions FS may be arranged or provided sequentially from the right side to the left side of FIG. 3. One of the first electrode patterns 122 may be located or provided under and overlap with the first flat portion FS, and an other one of the first electrode patterns 122 may be located or provided under and overlap with the third flat portion FS. In one or more embodiments, an other one of the first electrode patterns 122 may be located or provided under and overlap with the fifth flat portion FS. In one or more embodiments, one of the second electrode patterns 123 may be located or provided under and overlap with the second flat portion FS, and one of the ground patterns 124 may be located or provided under and overlap with the fourth flat portion FS.

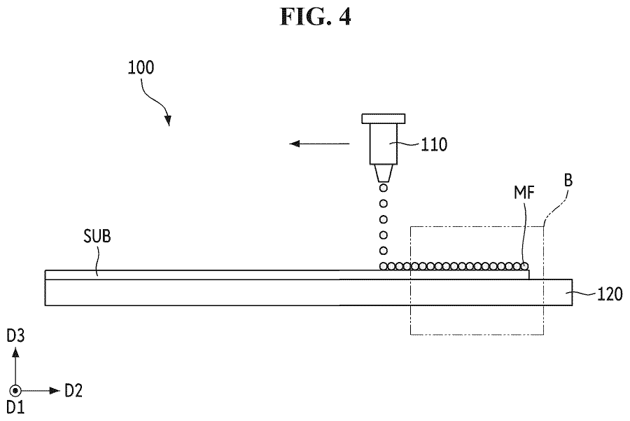

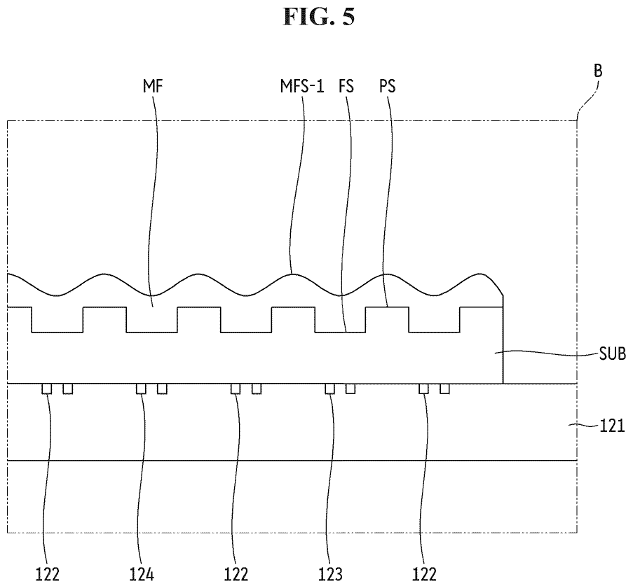

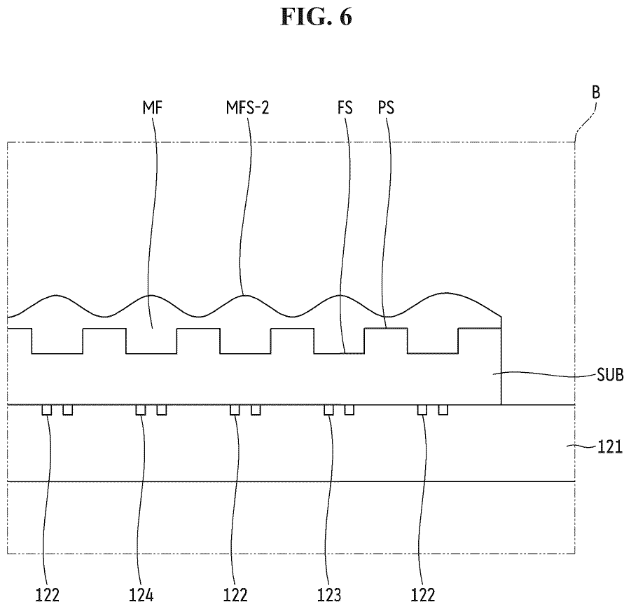

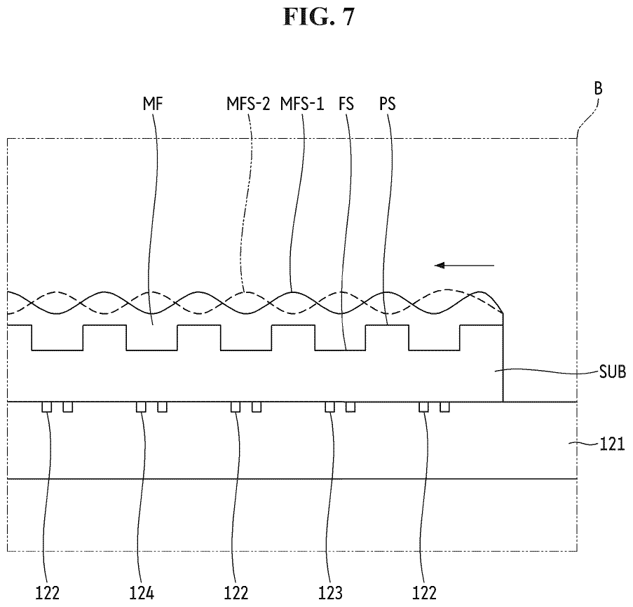

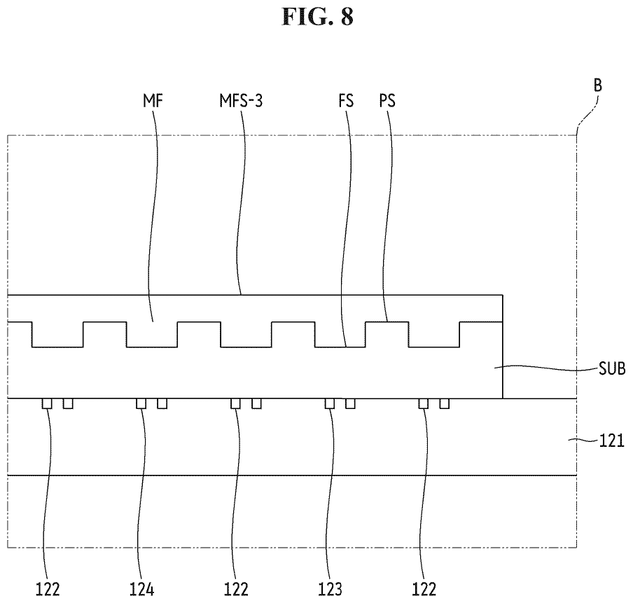

FIG. 4 is a view illustrating the supply nozzle of FIG. 1 that supplies a chemical liquid onto a substrate. FIG. 5 is an enlarged view of portion B of FIG. 4. FIG. 6 is a view illustrating that AC voltage being less than the DC voltage applied to the first electrode pattern is applied to the second electrode pattern in FIG. 5. FIG. 7 is a view illustrating the states of FIGS. 5 and 6 at the same time. FIG. 8 is a view illustrating that the surface of the chemical liquid becomes even (e.g., substantially even) after the process of FIG. 7.

Hereinafter, a process of forming or providing a thin film on the substrate SUB by the apparatus for forming or providing a thin film according to one or more embodiments of the present disclosure will be described in more detail with reference to FIGS. 4 to 8.

Referring to FIG. 4, a chemical liquid MF may be supplied onto the upper surface of a substrate SUB by the supply nozzle 110. The supply nozzle 110 may be horizontally (e.g., substantially horizontally) movable above the substrate SUB so that (e.g., such that) the chemical liquid MF is supplied to the entire (e.g., substantially entire) upper surface of the substrate SUB.

Referring to FIG. 5, after the chemical liquid MF is supplied to the upper surface of the substrate SUB by the supply nozzle 110, the voltage of 2 kV may be applied to the first electrode pattern 122 and the second electrode pattern 123, while the voltage of 0 kV may be applied to the ground electrode 124. Because there is no potential difference between the first electrode pattern 122 and the second electrode pattern 123, a surface MFS-1 of the chemical liquid MF where a protruding portion PS of the substrate SUB is located or provided may protrude upwardly of the substrate SUB. In one or more embodiments, the upper surface of the chemical liquid MF may be uneven and bumpy.

Referring to FIG. 6, the voltage of 2 kV may be applied to the first electrode pattern 122, the voltage of −2 kV may be applied to the second electrode pattern 123, and the voltage of 0 kV may be applied to the ground electrode 124. Because the chemical liquid MF may flow from a high voltage level to a low voltage level, a surface MFS −2 of the chemical liquid MF where a flat portion FS of the substrate SUB is located or provided may protrude upwardly of the substrate SUB.

Referring to FIGS. 7 and 8, as the voltage applied to the second electrode pattern 123 changes in the range of −2 kV to 2 kV, a potential difference occurs between the first electrode pattern 122 and the second electrode pattern 123, and the protruding portion of the surface of the chemical liquid MF may move from the right side to the left side of FIG. 7 due to the potential difference between the first electrode pattern 122 and the second electrode pattern 123. In this manner, as the protruding portion of the surface of the chemical liquid MF continues to move in the horizontal direction, a surface MFS-3 of the chemical liquid MF may become flat (e.g., substantially flat), as illustrated in FIG. 8. In one or more embodiments, the upper surface of the chemical liquid MF may become even (e.g., substantially even). As the upper surface of the chemical liquid MF becomes even (e.g., substantially even), the surface of the thin film formed or provided on the substrate SUB may become even (e.g., substantially even).

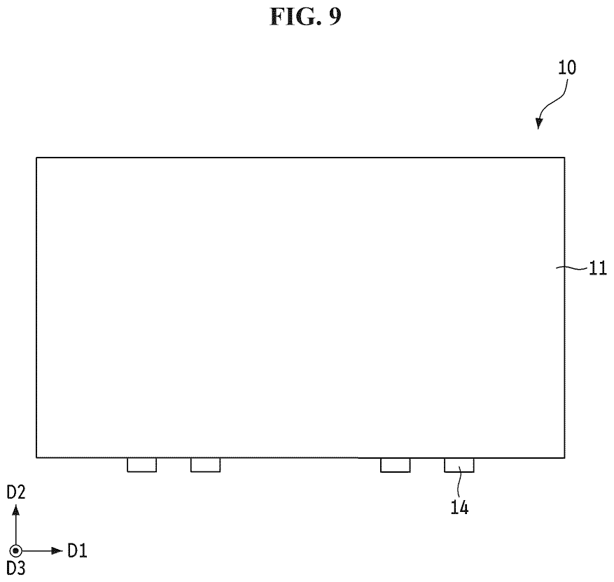

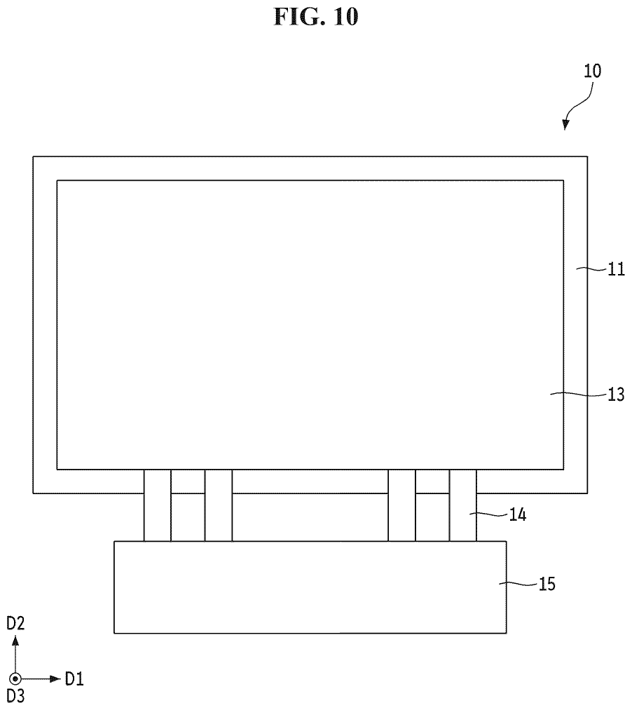

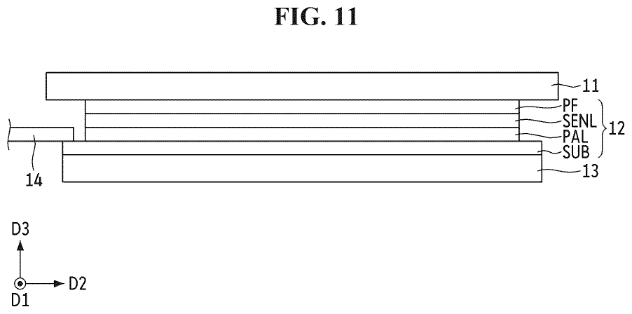

FIG. 9 is a plan view illustrating a display device fabricated by the apparatus for forming or providing a thin film according to one or more embodiments of the present disclosure if (e.g., when) a connecting member is folded. FIG. 10 is a plan view illustrating the display device of FIG. 9 if (e.g., when) the connecting member is unfolded. FIG. 11 is a side view illustrating a part of FIG. 10.

A display device 10 fabricated by the apparatus 100 for forming or providing a thin film according to one or more embodiments of the present disclosure may be a light-emitting display device, such as an organic light-emitting display device utilizing organic light-emitting diodes, a quantum-dot light-emitting display device including quantum-dot light-emitting layer, an inorganic light-emitting display device including an inorganic semiconductor, and/or a micro light-emitting display device utilizing micro light-emitting diodes (LED). In the following description, an organic light-emitting display device is described as an example of the display device 10. It is, however, to be understood that embodiments of the present disclosure are not limited thereto.

The display device 10 may have a quadrangular (e.g., substantially quadrangular) shape, such as a rectangular (e.g., substantially rectangular) shape if (e.g., when) viewed from the top. For example, the display device 10 may have a rectangular (e.g., substantially rectangular) shape having longer sides in the first direction D1 and shorter sides in the second direction D2 if (e.g., when) viewed from the top. The corners where the longer sides in the first direction D1 meet the shorter sides in the second direction D2 may be rounded with a set or predetermined curvature or may be a right angle. The shape of the display device 10 if (e.g., when) viewed from the top is not limited to a rectangular (e.g., substantially rectangular) shape but may be formed or provided in another polygonal (e.g., substantially polygonal) shape, a circular (e.g., substantially circular) shape, or an elliptical (e.g., substantially elliptical) shape.

Referring to FIGS. 9 to 11, the display device 10 fabricated by the apparatus 100 according to one or more embodiments of the present disclosure may include a cover window 11, a display panel 12, a panel bottom member 13, a connecting member 14, and a driver circuit board 15.

The cover window 11 may include a material having high light transmittance. The cover window 11 may include a polymer resin, such as polyimide and/or glass. The cover window 11 may be attached onto a polarizing film PF of the display panel 12 by an adhesive member, such as an optically clear adhesive (OCA) film.

The display panel 12 may be disposed or provided under the cover window 11. The display panel 12 may have a rectangular (e.g., substantially rectangular) shape having longer sides in the first direction D1 and shorter sides in the second direction D2 if (e.g., when) viewed from the top. In the display panel 12, the corners where the longer sides in the first direction D1 meet the shorter sides in the second direction D2 may be formed or provided at a right angle or may be rounded with a set or predetermined curvature. The display panel 12 may have a quadrangular (e.g., substantially quadrangular) shape other than a rectangular (e.g., substantially rectangular) shape, a polygonal (e.g., substantially polygonal) shape other than a quadrangular (e.g., substantially quadrangular) shape, a circular (e.g., substantially circular) shape, an oval (e.g., substantially oval) shape, or an irregular shape if (e.g., when) viewed from the top.

The display panel 12 may include a display area where a plurality of emission areas that emits light is arranged or provided and a non-display area disposed or provided around the display area. The non-display area may be around (e.g., surround) the display area. A plurality of display pads may be disposed or provided in the non-display area at one edge of the display panel 12.

The display panel 12 may include a substrate SUB, a display unit PAL, a sensor unit SENL, and a polarizing film PF.

The substrate SUB may be made of an insulating (e.g., electrically insulating) material, such as glass, quartz, and/or a polymer resin. The substrate SUB may be a rigid substrate or a flexible substrate that may be bent, folded, rolled, and/or the like.

The display unit PAL may be disposed or provided on the substrate SUB. The display unit PAL may be a layer including a plurality of emission areas that emit light. The display unit PAL may include a buffer film, a thin-film transistor layer on which thin-film transistors are disposed or provided, a light-emitting element layer that emits light, and/or an encapsulating layer for encapsulating the light-emitting element layer.

The sensor unit SENL may be disposed or provided on the display unit PAL. The sensor unit SENL may include sensor electrodes and may sense whether there is a user's touch.

The polarizing film PF may be disposed or provided on the sensor unit SENL. The polarizing film PF may prevent the deterioration (or reduce a degree or occurrence of the deterioration) of image visibility of the display panel 200 due to reflection of external light. The polarizing film may include a linear polarizer and a retardation film, such as a λ/4 (quarter-wave) plate. The phase retardation film may be disposed or provided on the sensor unit SENL, and the linear polarizer may be disposed or provided on the phase retardation film. The cover window 11 may be disposed or provided on the polarizing film PF.

The panel bottom member 13 may be disposed or provided under the substrate SUB. The panel bottom member 13 may be attached to the lower surface of the substrate SUB by an adhesive member. The adhesive member may be a pressure-sensitive adhesive (PSA). The panel bottom member 13 may include at least one selected from among a light-absorbing member to absorb light incident from outside, a buffer member to absorb external impact, and a heat dissipating member to efficiently or suitably discharge heat from the display panel 12.

The light-absorbing member may be disposed or provided under the substrate SUB. The light-absorbing member may block the transmission of light to prevent the elements disposed or provided thereunder, such as the driver circuit board 15, from being seen from above the display panel 12 (or to reduce a degree to or occurrence of which the elements disposed or provided thereunder, such as the driver circuit board 15, are seen from above the display panel 12). The light-absorbing member may include a light-absorbing material, such as a black pigment and/or a black dye.

The buffer member may be disposed or provided under the light-absorbing member. The buffer member may absorb an external impact to prevent the display panel 12 from being damaged (or to reduce a degree to or occurrence of which the display panel 12 is damaged). The buffer member may be made up or composed of a single layer or multiple layers. For example, the buffer member may be formed or composed of a polymer resin, such as polyurethane, polycarbonate, polypropylene, and/or polyethylene, or may be formed or composed of a material having elasticity, such as a rubber and/or a sponge obtained by foaming a urethane-based material and/or an acrylic-based material.

The heat dissipating member may be disposed or provided under the buffer member. The heat dissipation member may include a first heat dissipation layer including graphite and/or carbon nanotubes, and a second heat dissipation layer formed or composed of a thin metal film, such as copper, nickel, ferrite, and/or silver, which may block electromagnetic waves and have high thermal conductivity.

The connecting member 14 may be connected to a plurality of display pads of the display panel 12 through a conductive (e.g., electrically conductive) adhesive member, such as an anisotropic conductive film. Accordingly, the display panel 12 and the connecting member 14 may be electrically connected with each other.

In one or more embodiments, the connecting member 14 may be connected to a plurality of circuit pads of the driver circuit board 15 through a conductive (e.g., electrically conductive) adhesive member, such as an anisotropic conductive film. As a result, the connecting member 14 and the driver circuit board 15 may be electrically connected with each other.

The connecting member 14 may be a flexible printed circuit board (FPCB) or a chip-on film.

The driver circuit board 15 may be disposed or provided under the panel bottom member 13 if (e.g., when) the connecting member 14 is bent. The driver circuit board 15 may be a flexible printed circuit board that may be bent, a rigid printed circuit board (PCB) that is not easily bent, or a composite printed circuit board including both (e.g., simultaneously) a rigid printed circuit board and a flexible printed circuit board.

The driver circuit board 15 may process the signal converted by a control circuit board to transmit it to the display panel 12. The driver circuit board 15 may be electrically connected to the display panel 12 by the connecting member 14.

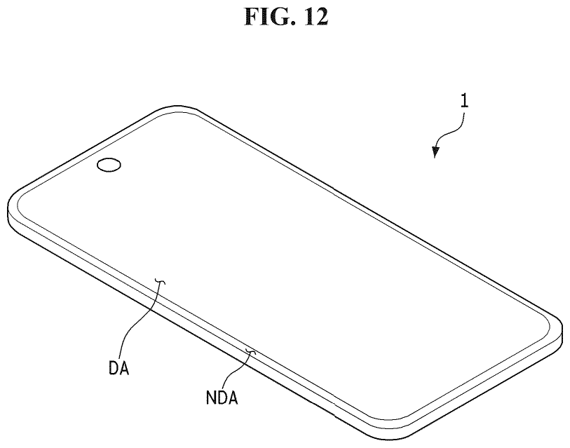

FIG. 12 is a perspective view of an electronic device fabricated by the apparatus for forming or providing a thin film according to one or more embodiments of the present disclosure.

Referring to FIG. 12, an electronic device 1 fabricated by the apparatus 100 for forming or providing a thin film according to one or more embodiments of the present disclosure may include a display device 10 that provides a display screen. Examples of the electronic device 1 may include, but are not limited to, a mobile phone, a smart phone, a tablet PC, a mobile communications terminal, an electronic organizer, an e-book, a personal digital assistant (PDA), a portable multimedia player (PMP), a navigation device, an ultra mobile PC (UMPC), a television set, a game machine, a wristwatch-type or kind electronic device, a head-mounted display, a personal computer monitor, a laptop computer, a vehicle instrument cluster, a digital camera, a camcorder, an outdoor billboard, an electronic billboard, one or more suitable medical apparatuses, one or more suitable inspection devices, one or more suitable home appliances including a display area, such as a refrigerator and/or a laundry machine, internet of things (IoT) devices, and/or the like. Examples of the electronic device 1 may include, but are not limited to, a smartphone, a tablet PC, a laptop computer, and/or the like.

The electronic device 1 may include a display area DA and a non-display area NDA. The shape of the display area DA may follow the shape of the electronic device 1 if (e.g., when) viewed from the top. For example, if (e.g., when) the electronic device 1 has a rectangular (e.g., substantially rectangular) shape if (e.g., when) viewed from the top, the display area DA may also have a rectangular (e.g., substantially rectangular) shape if (e.g., when) viewed from the top.

The display area DA may include a plurality of pixels of the display device 10 to display images. The non-display area NDA may display no image because it does not include the pixels of the display device 10. The non-display area NDA may be disposed or provided around the display area DA. The non-display area NDA may be around (e.g., surround) the display area DA, but embodiments of the present disclosure are not limited thereto. The display area DA may be partially surrounded by the non-display area NDA.

It should be understood, however, that the aspects and features of embodiments of the present disclosure are not restricted to the one set forth herein. The above and other aspects and features of certain embodiments of the present disclosure will become more apparent to one of ordinary skill in the art to which the present disclosure pertains by referencing the appended claims, with equivalents thereof to be included therein.

What is claimed is:

1. An apparatus for providing a thin film, the apparatus comprising:
an electrostatic chuck to absorb and support a substrate; and
a supply nozzle to supply chemical liquid onto the substrate, and
wherein the electrostatic chuck comprises:
a base;
at least one first electrode pattern on the base;
at least one second electrode pattern provided on the base and spaced apart from the at least one first electrode pattern; and
at least one ground pattern provided on the base and spaced apart from the at least one first electrode pattern and the at least one second electrode pattern.

2. The apparatus as claimed in claim 1, wherein the at least one first electrode pattern comprises a plurality of first electrode patterns, the at least one second electrode pattern comprises a plurality of second electrode patterns, and the at least one ground pattern comprises a plurality of ground patterns, and
wherein the plurality of first electrode patterns, the plurality of second electrode patterns, and the plurality of ground patterns are provided sequentially and repeatedly.

3. The apparatus as claimed in claim 2, wherein the plurality of second electrode patterns and the plurality of ground patterns are between the plurality of first electrode patterns.

4. The apparatus as claimed in claim 2, wherein one of the plurality of second electrode patterns is between one of the plurality of first electrode patterns and an other one of the plurality of first electrode patterns, and
wherein one of the plurality of ground patterns is spaced apart from the other one of the plurality of first electrode patterns such that the other one of the plurality of first electrode patterns is between the one of the plurality of ground patterns and the one of the plurality of second electrode patterns.

5. The apparatus as claimed in claim 2, wherein the plurality of first electrode patterns, the plurality of second electrode patterns, and the plurality of ground patterns are extended in a first direction, and
wherein the plurality of first electrode patterns, the plurality of second electrode patterns, and the plurality of ground patterns are spaced apart from one another in a second direction crossing the first direction.

6. The apparatus as claimed in claim 5, wherein the plurality of first electrode patterns, the plurality of second electrode patterns, and the plurality of ground patterns are in an order of a first electrode pattern, a second electrode pattern, an other first electrode pattern, and a ground pattern.

7. The apparatus as claimed in claim 5, wherein the substrate comprises:
at least one flat portion on the substrate; and
at least one protruding portion protruding from the at least one flat portion upwardly of the substrate, and
wherein the at least one flat portion comprises a plurality of flat portions and the at least one protruding portion comprises a plurality of protruding portions, and the plurality of flat portions and the plurality of protruding portions are provided alternately with each other, and
wherein the plurality of first electrode patterns, the plurality of second electrode patterns, and the plurality of ground patterns overlap with the plurality of flat portions.

8. The apparatus as claimed in claim 7, wherein the plurality of flat portions and the plurality of protruding portions are extended in the first direction and provided alternately in the second direction.

9. The apparatus as claimed in claim 7, wherein the plurality of flat portions comprises a first flat portion, a second flat portion, a third flat portion, and a fourth flat portion, and
wherein one of the plurality of first electrode patterns overlaps with the first flat portion, one of the plurality of second electrode patterns overlaps with the second flat portion, an other one of the plurality of first electrode patterns overlaps with the third flat portion, and one of the plurality of ground patterns overlaps with the fourth flat portion.

10. The apparatus as claimed in claim 1, wherein DC voltage is applied to the at least one first electrode pattern, AC voltage is applied to the at least one second electrode pattern, and ground voltage is applied to the at least one ground pattern.

11. The apparatus as claimed in claim 10, wherein a maximum value of the AC voltage applied to the at least one second electrode pattern is equal to or less than the DC voltage applied to the at least one first electrode pattern.

12. An electronic device comprising a display device fabricated by an apparatus for providing a thin film, wherein the apparatus comprises:
an electrostatic chuck to absorb and support a substrate; and
a supply nozzle to supply chemical liquid onto the substrate, and
wherein the electrostatic chuck comprises:
a base;
at least one first electrode pattern on the base;
at least one second electrode pattern provided on the base and spaced apart from the at least one first electrode pattern; and
at least one ground pattern provided on the base and spaced apart from the at least one first electrode pattern and the at least one second electrode pattern.

13. The electronic device as claimed in claim 12, wherein the at least one first electrode pattern comprises a plurality of first electrode patterns, the at least one second electrode pattern comprises a plurality of second electrode patterns, and the at least one ground pattern comprises a plurality of ground patterns, and
wherein the plurality of first electrode patterns, the plurality of second electrode patterns, and the plurality of ground patterns are provided sequentially and repeatedly.

14. The electronic device as claimed in claim 13, wherein the plurality of second electrode patterns and the plurality of ground patterns are between the plurality of first electrode patterns.

15. The electronic device as claimed in claim 13, wherein one of the plurality of second electrode patterns is between one of the plurality of first electrode patterns and an other one of the plurality of first electrode patterns, and
wherein one of the plurality of ground patterns is spaced apart from the other one of the plurality of first electrode patterns such that the other one of the plurality of first electrode patterns is between the one of the plurality of ground patterns and the one of the plurality of second electrode patterns.

16. The electronic device as claimed in claim 13, wherein the plurality of first electrode patterns, the plurality of second electrode patterns, and the plurality of ground patterns are extended in a first direction, and
wherein the plurality of first electrode patterns, the plurality of second electrode patterns, and the plurality of ground patterns are spaced apart from one another in a second direction crossing the first direction.

17. The electronic device as claimed in claim 16, wherein the substrate comprises:
at least one flat portion on the substrate; and
at least one protruding portion protruding from the at least one flat portion upwardly of the substrate, and
wherein the at least one flat portion comprises a plurality of flat portions and the at least one protruding portion comprises a plurality of protruding portions, and the plurality of flat portions and the plurality of protruding portions are provided alternately with each other, and
wherein the plurality of first electrode patterns, the plurality of second electrode patterns, and the plurality of ground patterns overlap with the plurality of flat portions.

18. The electronic device as claimed in claim 17, wherein the plurality of flat portions and the plurality of protruding portions are extended in the first direction and provided alternately in the second direction.

19. The electronic device as claimed in claim 17, wherein the plurality of flat portions comprises a first flat portion, a second flat portion, a third flat portion, and a fourth flat portion, and
wherein one of the plurality of first electrode patterns overlaps with the first flat portion, one of the plurality of second electrode patterns overlaps with the second flat portion, an other one of the plurality of first electrode patterns overlaps with the third flat portion, and one of the plurality of ground patterns overlaps with the fourth flat portion.

20. The electronic device as claimed in claim 12, wherein DC voltage is applied to the at least one first electrode pattern, AC voltage is applied to the at least one second electrode pattern, and ground voltage is applied to the at least one ground pattern.
